(19) United States
(12) Patent Application Publication
(10) Pub. No.: US 2011/0151617 A1
(43) Pub. Date: Jun. 23, 2011

(54) Memory and methods of forming the same to enhance scalability of non-volatile two-terminal memory cells

(75) Inventor: Julie Casperson Brewer, Santa Clara, CA (US)

(73) Assignee: UNITY SEMICONDUCTOR CORPORATION, SUNNYVALE, CA (US)

(21) Appl. No.: 12/653,895

(22) Filed: Dec. 18, 2009

(51) Int. Cl. H01L 21/16

(52) U.S. Cl. 438/104; 257/E21.078

(57) ABSTRACT

Embodiments of the invention relate generally to semiconductors and memory technology, and more particularly, to systems, integrated circuits, and methods to scale memory elements, such as implemented in BEOL third dimensional memory technology, independent of operational characteristics. In at least some embodiments, a method to fabricate a non-volatile two-terminal memory device includes depositing a first electrode at a first temperature in a first region in relation to a substrate (e.g., a silicon wafer) that includes active circuitry that was previously fabricated FEOL on the substrate, fabricating a memory element coupled to the first electrode, and optionally, forming at least a portion of a non-ohmic device electrically coupled with the memory element. Further, the method can include depositing a second electrode at a second temperature in a second region in relation to the substrate. In some embodiments, the second temperature is approximately equal to or greater than the first temperature.

### FIELD OF THE INVENTION

Embodiments of the invention relate generally to semiconductors and memory technology, and more particularly, to systems, integrated circuits, and methods to scale memory elements, such as memory implemented in third dimensional memory technology, independent of operational characteristics.

### BACKGROUND

Reliable operation of resistive memory technologies typically requires that memory cells operate with relatively consistent operational characteristics to effectively retain information in a non-volatile manner. In some memory technologies, the operational characteristics may vary with the size of the memory cell, which, in turn, may impede efforts to reduce the size of the memory cells.

It would be desirable to provide improved systems, integrated circuits, and methods that minimize one or more of the drawbacks associated with conventional techniques for scaling memory cells.

### BRIEF DESCRIPTION OF THE DRAWINGS

The invention and its various embodiments are more fully appreciated in connection with the following detailed description taken in conjunction with the accompanying drawings, in which:

FIG. 1 depicts a memory cell fabricated in accordance with various embodiments of the invention;

FIG. 2 is a diagram depicting examples of operational characteristics associated with scaled structures formed in accordance with embodiments of the invention;

FIG. 3 is a diagram depicting a relationship between an operational characteristic of a two-terminal memory cell and one or more dimensions of a cross-sectional area, according to embodiments of the invention;

FIG. 4 depicts a current-voltage relationship as an operational characteristic of a memory cell, according to various embodiments of the invention;

FIG. 5 depicts a flow for forming a non-volatile two-terminal memory cell that is scalable to provide different sizes while maintaining a uniform operational characteristic, according to various embodiments of the invention;

FIG. 6 depicts an example of a scalable array of memory cells each including a scalable memory element formed as part of a scalable memory cell, according to various embodiments of the invention; and

FIG. 7 depicts a side view of an exemplary memory cell formed in accordance with techniques described herein between conductive array lines, according to one or more embodiments.

Like reference numerals refer to corresponding parts throughout the several views of the drawings. Note that most of the reference numerals include one or two left-most digits that generally identify the figure that first introduces that reference number.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

U.S. patent application Ser. No. 11/095,026, filed Mar. 30, 2005, published as U.S. Pub. No. 2006/0171200, and entitled “Memory Using Mixed Valence Conductive Oxides,” which is herein incorporated by reference in its entirety and for all purposes, describes non-volatile third dimensional memory elements that may be arranged in a two-terminal, cross-point memory array that can be configured as a single layer of cross-point memory or as multiple vertically stacked layers of cross-point memory. New memory structures are possible with the capability of this third dimensional memory array. In at least some embodiments, a two-terminal memory element or memory cell can be configured to change conductivity when exposed to an appropriate voltage drop across the two-terminals. The memory element can include an electronically insulating layer (e.g., an electrolytic tunnel barrier layer) in contact with one or more layers of a conductive oxide material (e.g., a mixed valence conductive oxide or a binary oxide). The electronically insulating layer and the one or more layers of the conductive oxide material are electrically in series with one another. A voltage drop across the electronically insulating layer can cause an electrical field within the conductive oxide layer that is strong enough to move oxygen ions out of the conductive oxide layer and into the electronically insulating layer. When certain conductive oxide materials (e.g., praseodymium-calcium-manganese-oxygen perovskites and lanthanum-nickel-oxygen perovskites) change valence, their conductivity changes. Additionally, oxygen accumulation in certain electronically insulating materials (e.g., yttrium stabilized zirconia) can also change conductivity. If a portion of the conductive oxide layer near the electronically insulating layer becomes less conductive, a tunnel barrier width effectively increases. If the electronically insulating layer becomes less conductive, the tunnel barrier height effectively increases. Both mechanisms can be reversible if the excess oxygen from the electronically insulating layer flows back into the conductive oxide layer. A memory can be designed to exploit tunnel barrier height modification, tunnel barrier width modification, or both. The technology allows for the emulation of other memory technologies by duplicating the interface signals and protocols, while accessing the third dimensional memory array. The third dimensional memory array may emulate other types of memory, providing memory combinations within a single component. To illustrate the functionality of a third dimensional memory element, consider that the third dimensional memory element switches to a low resistive state in response to a first write voltage, and switches to a high resistive state when a second write voltage is applied. In some examples, the first write voltage may be opposite in polarity from the second write voltage. The resistance of the memory element may be adjusted by the voltage differential across the memory element. As such, the two terminals of the memory element may be coupled to one or more variable voltage sources to create a voltage differential across the two terminals. For example, a first terminal of the memory element may be programmed to be a certain voltage between, for instance, +3 Volts and −3 Volts. Further, a second terminal of the memory element may be programmed to be another voltage between, for instance, +3 Volts and −3 Volts.

In some embodiments, an electronically insulating layer and one or more conductive oxide structures do not need to operate in a silicon substrate, and, therefore, can be fabricated (e.g., back-end-of-the-line BEOL) above circuitry being used for other purposes (e.g., active circuitry previously fabricated front-end-of-the-line FEOL). Further, a two-terminal memory cell can be arranged as a cross point such that one terminal is electrically coupled with an X-direction line (or an “X-line”) and the other terminal is electrically coupled with a Y-direction line (or a “Y-line”). A third dimensional memory can include multiple memory cells vertically stacked upon one another, sometimes sharing X-direction and Y-direction lines in a layer of memory, and sometimes having isolated lines. When a first write voltage, VW1, is applied across the memory cell (e.g., by applying ½ VW1 to the X-direction line and ½ -VW1 to the Y-direction line), the memory cell can switch to a low resistive state. When a second write voltage, VW2, is applied across the memory cell (e.g., by applying ½ VW2 to the X-direction line and ½ -VW2 to the Y-direction line), the memory cell can switch to a high resistive state. Memory cells using electrolytic tunnel barriers and mixed valence conductive oxides can have VW1 opposite in polarity from VW2.

Accordingly, the memory cells based on non-volatile memory can be fabricated BEOL over circuitry previously fabricated FEOL on a substrate (e.g., a silicon—Si wafer). An inter-level interconnect structure can be used to electrically couple the BEOL memory cells with the FEOL circuitry in the substrate below. Furthermore, the memory cells can be fabricated along with a two-terminal cross-point memory array that is fabricated BEOL above the aforementioned FEOL circuitry positioned on the substrate below. The FEOL circuitry fabricated on the substrate below (e.g., CMOS circuitry) can include circuitry for performing data operations (e.g., read, write, program, and erase) on two-terminal memory cells positioned in the two-terminal cross-point memory array and operative to store data as a plurality of conductivity profiles. The same or different FEOL circuitry can be used to access the memory cells.

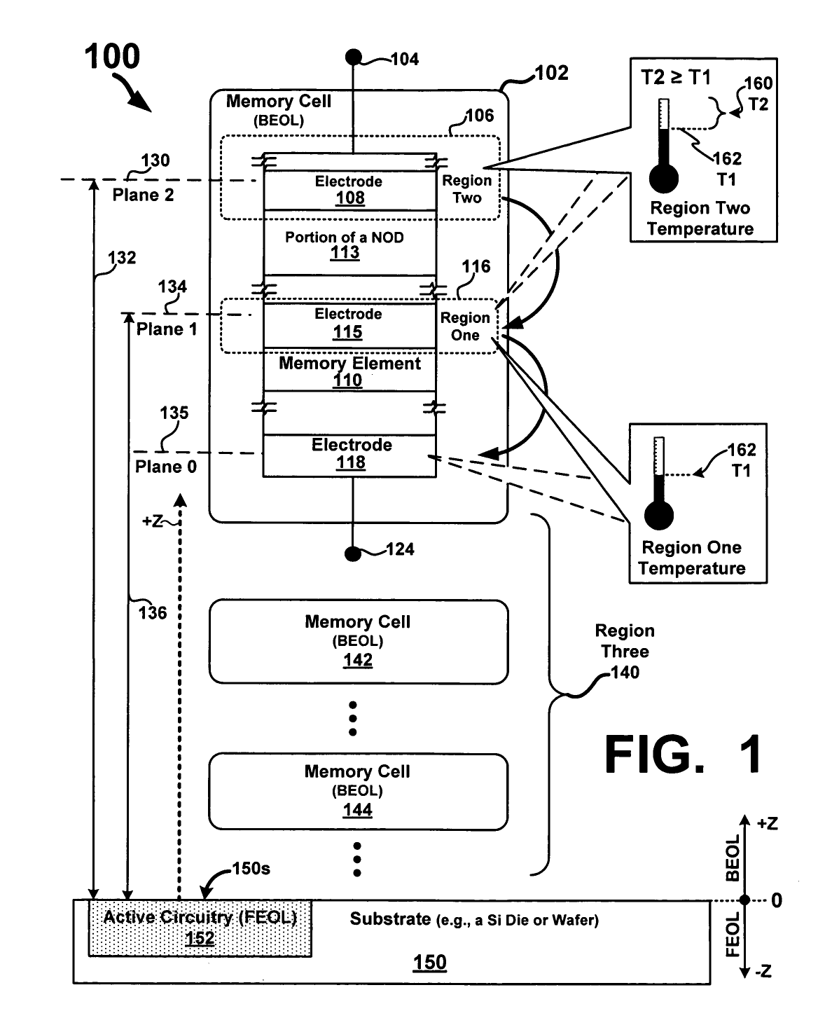

FIG. 1 depicts a memory cell fabricated in accordance with various embodiments of the invention. In this example, a two-terminal memory device 100 includes terminals 104 and 124 and a memory cell 102, which is formed to include at least a memory element 110, a portion of a non-ohmic device (“NOD”) 113, an electrode 108, an electrode 115, and an electrode 118. As used herein, the term “memory cell” can refer, at least in some embodiments, to various layers of materials, including memory material(s) constituting, for example, a memory element and optionally, a non-ohmic device, arranged between conductive lines and electrically in series with the conductive lines. When the NOD 113 is included with the memory cell 102, the memory element 110 and the NOD 113 are electrically in series with each other and with the terminals 104 and 124. Examples of conductive lines can include but are not limited to the terminals 104 and 124 and/or conductive array lines in a cross-point array as will be described in greater detail below. Operating characteristics of either the NOD 113 or memory element 110, or both, can be enhanced for purposes of scaling memory cell 102 or any of its constituent structures, according to various embodiments. For example, the fabrication of electrode 108 (or equivalent) and electrode 115 (or equivalent) can enhance the operating characteristics of the NOD 113, whereas the fabrication of electrode 115 (or equivalent) and electrode 118 can enhance the operating characteristics of at least memory element 110.

In at least some embodiments, electrode 115 is formed by depositing a material at a temperature (“T1”) 162 in region one 116, and electrode 108 is formed by depositing a material at a temperature (“T2”) 160 within a range of temperatures in region two 106. That is, temperature 160 can be substantially equal to or greater than temperature 162, according to one or more embodiments. Temperature 160 and temperature 162 of respective region one 116 and region two 106 can be implemented in different phases of fabrication of memory device 100. In at least one embodiment, temperature 162 is approximately 300 degrees Celsius (° C.) or higher. Electrode 108 and electrode 115 can be an electrically conductive material including but not limited to platinum (Pt), gold (Au), silver (Ag), iridium (Ir), ruthenium (Ru), palladium (Pd), aluminum (Al), tungsten (W), a noble metal, a noble metal alloy, refractory metals and their alloys, copper (Cu) (e.g., encapsulated with a cladding layer to prevent oxidation of the Cu), tin oxide (SnOₓ), a conductive oxide material, or others. Region one 116 and region two 106 can be defined in terms of spatial dimensions and can include an electrode (or a space into which the electrode is deposited), an electrode and/or an adjacent conductive array line (not shown), or a group of conductive electrodes and/or array lines. Region one 116 and region two 106 can be coextensive with “Plane 1” 134 and “Plane 2” 130, respectively, whereby the planes can extend parallel (or substantially parallel) to a substrate 150 and through an electrode and/or a conductive array line. Here, the substrate 150 can include active circuitry (e.g., CMOS circuitry) fabricated FEOL on the substrate and in electrical communication with the memory cells fabricated BEOL above the substrate 150 (e.g., directly above and in contact with an upper surface 150s of substrate 150). The FEOL structure positioned along the −Z axis can include an inter-level interconnect structure (not shown) operative to electrically couple the active circuitry 152 with the BEOL structure (e.g., memory cells) positioned along the +Z axis. The substrate 150 can be a semiconductor substrate such as a silicon wafer or die singulated from a silicon wafer, for example. In alternative embodiments, region one 116 can be located to be coextensive with “Plane 0” 135 and region two 106 can be located to be coextensive with “Plane 1” 134. Therefore, electrode 118 can be formed in a region (e.g., region one) that is coextensive with “Plane 0” 135 by depositing a material at a temperature (“T1”) 162 in that region, and electrode 115 can be formed in another region (e.g., region two) that is coextensive with “Plane 1” 134 by depositing a material in that region at a temperature (“T2”) 160 within a range of temperatures (e.g., where temperature 160 is greater than or equal to temperature 162, that is T2≧T1).

In view of the foregoing, the structures and/or functionalities of memory cell 102, as well as electrode 108 and electrode 115, can enhance the stability of the operating characteristics of memory device 100 (and portions thereof) over variations, for example, in process and/or temperature, which, in turn, can enhance the scalability of one or more portions of memory cell 102 to facilitate scaling of the cross-sectional area of the memory cell (or a portion thereof) within a range of cross-sectional area values in which a magnitude of current density remains substantially constant. Further, the structure of memory cell 102 also can be scaled while having minimal or negligible effects on the current-voltage characteristics of memory cell 102 or portions thereof. At least one current-voltage characteristic is resistance that can be represented by an I-V curve, and the various techniques described herein can configure the structures and/or functionalities in memory cell 102 to provide for I-V symmetry (i.e., a symmetric I-V curve for ranges of negative and positive voltages). Therefore, changes (and rates of changes) in resistance in the negative and positive voltage ranges are substantially equivalent. In various embodiments, memory element 110 is a resistive state element configured to have multiple resistive states that can correspond to data stored in a non-volatile manner. In some embodiments, a cross-sectional area of, for example, memory element 110 can be scaled with minimal or negligible effects on the reliable operation as a storage device. For example, a structure of memory cell 102 can be scaled while having minimal or negligible effects on the current-voltage characteristics of memory cell 102, whereby memory cell 102 is in a relatively high resistive state for a first set of voltages and is in a relatively low resistive state for a second set of voltages.

In some embodiments, a metal-insulator-metal (“MIM”) structure (not shown) or a portion thereof (not shown) can be implemented as portion of NOD 113 disposed between electrodes 115 and 108. In at least one example, electrode 108 is a metal layer of an MIM structure. Therefore, a cross-sectional area of, for example, portion of NOD 113 can be scaled with minimal or negligible effects on the reliable operation as a storage device. Further, the structures of portion of NOD 113 or electrode 108 can be scaled while having minimal or negligible effects on the current-voltage characteristics of memory cell 102 or portions thereof. According to some embodiments, the various techniques described herein can reduce the influence of one or more filamentary conduction paths on the current-voltage characteristics and/or current density. Filamentary conduction paths may be formed as an artifact of fabrication and/or operation of memory cell 102 and may conduct the same amount of current regardless of the size of memory cell 102 and its constituent structures. Such filamentary conduction paths, in some instances, may dominate current conduction, which, in turn, can increase ohmic heating or can influence operation of memory cell 102 in a manner that is other than designed.

In some embodiments, electrode 108 and electrode 115 can be formed by modifying the thermal energy of region one 116 to obtain temperature 162 during a first phase of forming memory cell 102, and modifying the thermal energy of region two 106 to obtain temperature 160 during a second phase. In some cases, the thermal energy of the material for forming electrode 108 and electrode 115 is modified (e.g., increased or decreased) to heat the material to temperatures 160 and 162, respectively, or, the thermal energy of both the material and the regions can be modified to elevate both the material and the regions to temperatures 160 and 162.

When lines 132 and 136 represent different distances, region one 116 and region two 106 can be disposed at different distances from substrate 150 (e.g., along the +Z axis) Thus, electrode 108 and electrode 115 can be formed above region three 140, which includes one or more other vertically stacked memory cells 142 and 144 in lower layers of memory. To form electrode 115 and electrode 108, a layer of memory cells is first identified, and then memory cell 102 is formed therein. Each layer of memory cells (e.g., along the +Z axis), such as the layer that includes memory cell 102, also can include region one 116 and region two 106 and can be positioned above (or below) one or more other layers of memory cells of a third dimension memory array. Thus, the first and second phases can be repeated for each layer of memory, whereby the formation of electrodes 115 and 108 each occurs once per layer of a stacked memory structure. When lines 132 and 136 represent different sets of one or more conductive paths, line 132 can represent a conductive path that is configured to communicate signals between electrode 108 (via terminal 104) and active circuitry 152, such as logic, formed in substrate 150. Similarly, line 136 can represent a conductive path that is configured to communicate signals between electrode 118 (via terminal 124) and active circuitry 152.

The various layers of materials can include a top terminal 104 that can be formed as part of, or in communication with, electrode 108. A bottom terminal 124 can be formed as part of, or in communication with, electrode 118. In some embodiments, electrodes 115 and 118 can be formed at temperatures of approximately 300° C. or higher, and can include platinum to enhance scalability of cross-sectional area of memory element 110 independent of the formation of electrode 108, whereas electrodes 115 and 108 can be formed at temperatures of approximately 300° C. or higher, and can include platinum to enhance scalability of cross-sectional area of portion of NOD 113 independent of the formation of electrode 118. In one embodiment, electrodes 118, 115, and 108 each can be formed at equivalent temperatures.

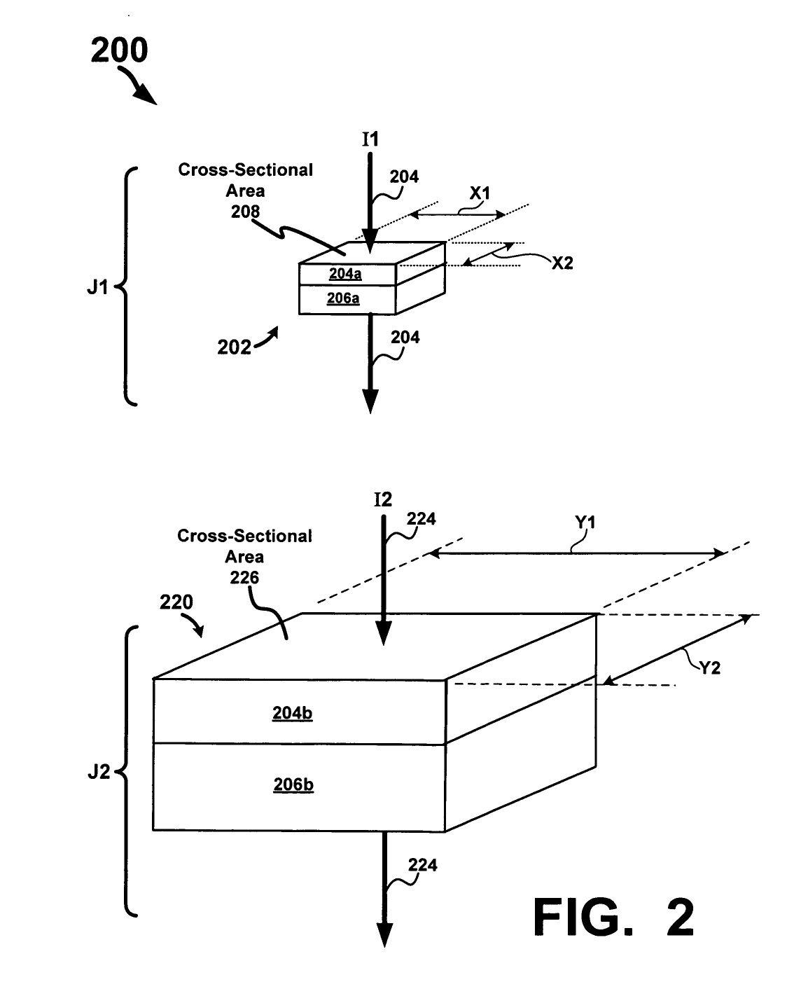

FIG. 2 is a diagram depicting examples of operational characteristics associated with scaled structures formed in accordance with embodiments of the invention. Diagram 200 depicts cross-sectional areas of two memory elements in which one memory element is a scaled version of the other memory element. Memory element 202 is shown having a cross-sectional area 208 into which a current (“I1”) 204 is applied, where cross-sectional area 208 can be defined by dimensions X1 and X2. The current density associated memory element 202 is represented as J1. Memory element 220 is shown having a cross-sectional area 226 into which a current (“I2”) 224 is applied, where cross-sectional area 226 can be defined by dimensions Y1 and Y2. As an example, dimensions Y1 and Y2 can be scaled by a factor (e.g., a scaling factor) to form memory element 202 with dimensions X1 and X2. The current density associated memory element 220 is represented as J2. When memory element 202 and 220 are formed with electrodes (not shown) that are fabricated in accordance with the various embodiments, the current densities J1 and J2 can be substantially the same over, for example, a range of dimensions in which the current density is relatively constant and independent of the sizes of the cross-sectional areas 208 and 226. In some embodiments, memory element 202 can include an electronically insulating layer 204a and a conductive oxide layer 206a, whereas memory element 220 can include an electronically insulating layer 204b and a conductive oxide layer 206b. According to some embodiments, electronically insulating layer 204a and conductive oxide layer 206a can be formed between a bottom electrode and either a top electrode or an intervening electrode, such as electrode 115 of FIG. 1, or both. Similarly, electronically insulating layer 204b conductive oxide layer 206b can be formed between a bottom electrode and either a top electrode or an intervening electrode, or both. In some embodiments, cross-sectional areas 208 and 226 can represent cross-sectional areas of portions of differently scaled NODs, where each portion of a NOD includes an insulator structure or a metal structure of a MIM structure.

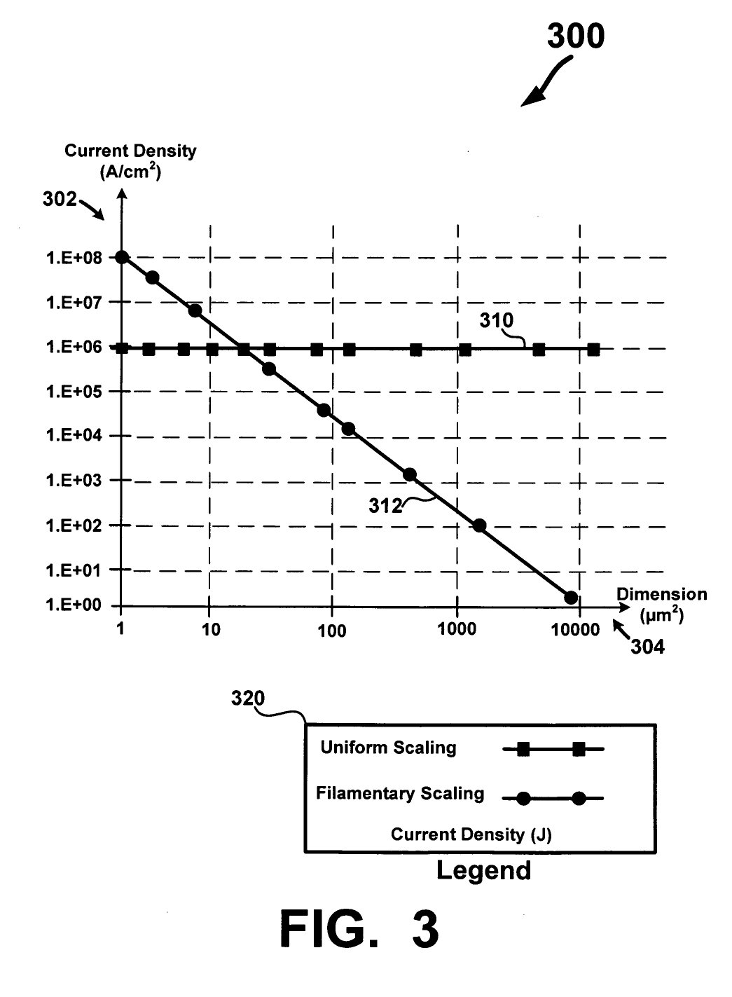

FIG. 3 is a diagram depicting a relationship between an operational characteristic of a two-terminal memory cell and one or more dimensions of a cross-sectional area, according to embodiments of the invention. In this example, diagram 300 depicts that the Y-axis represents values 302 of current density as an operational characteristic in units of current per unit area (e.g., A/cm²), and that the X-axis represents a dimension 304 of a cross-sectional area expressed in microns (“μm²”). Relationship 312 indicates that a current density is dependent on the dimension(s) of a cross-sectional area. Such a dependency can arise, at least in some instances, when filamentary conduction affects an operational characteristic, such as a current-voltage characteristic. This can occur when filamentary conduction contributes to the preponderance or to a predominant amount of current conduction for a memory cell. As depicted by relationship 312, the current density increases as the dimension size scales down (e.g., scales from 10,000 microns to 1 micron) and as the contribution of filamentary conduction increases. In accordance with various embodiments, memory cells formed consistent with one or more of the techniques described herein can have operational characteristics, such as current density, that approximate relationship 310. Relationship 310 depicts current density as being independent of the dimension(s) of a cross-sectional area, thereby providing for uniform scaling of two-terminal memory cells. That is, the dimensions of a two-terminal memory cell can scale or vary while the current density, current-voltage characteristics, or other operational characteristics remain uniform (or substantially uniform). In the example shown, a dimension of a cross-sectional area can be scaled from 10,000 microns to 1 micron while the current density remains relatively uniform or constant at 1.E+06 A/cm².

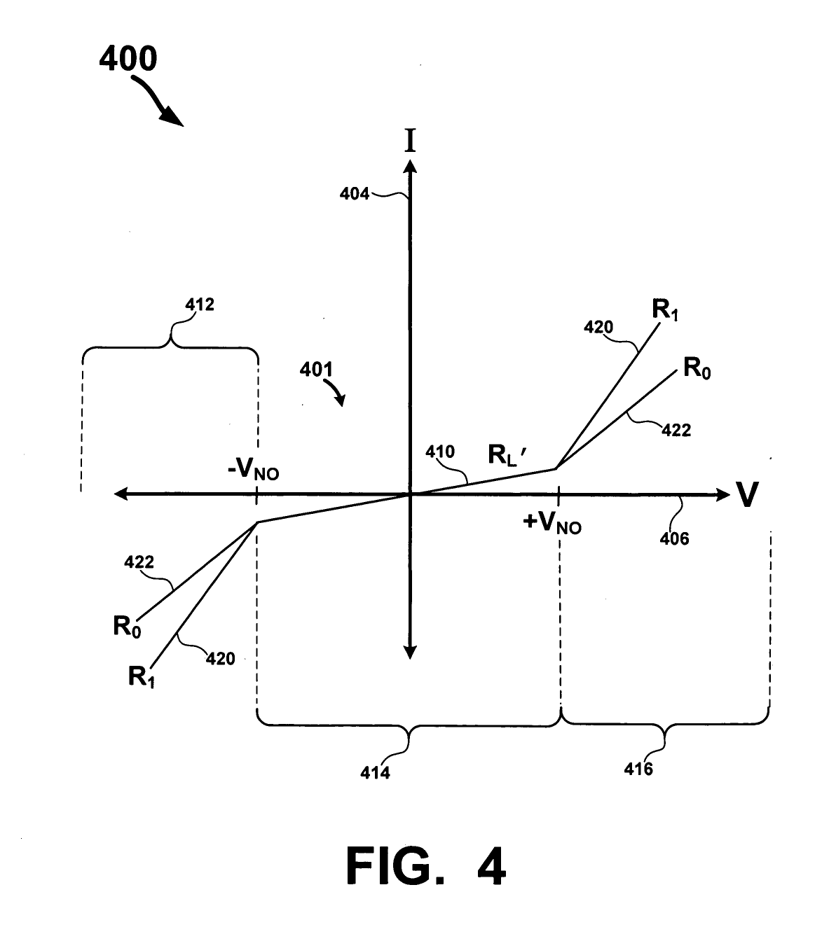

FIG. 4 depicts a current-voltage relationship as an operational characteristic of a memory cell, according to various embodiments of the invention. Here, current 404 (I) is depicted on a Y-axis as a function of voltage 406 (V) on an X-axis. Forming a memory cell in accordance with at least some embodiments provides for operation as expressed in a current-voltage relationship 401, within a range of cross-sectional area values over which the dimensions of the memory cell can scale. As shown in diagram 400, a memory cell operates with a relatively high resistance (“R_{L}”) 410 in a voltage range 414 between −V_{NO} and V_{NO}. In the negative voltage range 412 and positive voltage range 416, the resistance of the memory cell may split into two states: state (“R₁”) 420 and state (“R₀”) 422, whereby state 420 is the first operational resistive state and state 422 is the second operational resistive state. According to various embodiments, the formation of electrodes at certain temperatures and/or of certain metals can provide for enhanced I-V symmetry in ranges 412 and 416 than otherwise might be the case. In one example, the current-voltage relationship depicted in FIG. 4 is similar to that described in U.S. Patent Application No. 12/283,339, filed Sep. 11, 2008, and published as U.S. Pub. No. 2009/0016094 A1, entitled “Selection Device for Re-Writable Memory,” which is herein incorporated by reference in its entirety for all purposes. In some embodiments, platinum-based electrodes of a memory cell are formed at a temperature of approximately 300° C. or higher, provide a structure that can operate approximately to current-voltage relationship 401.

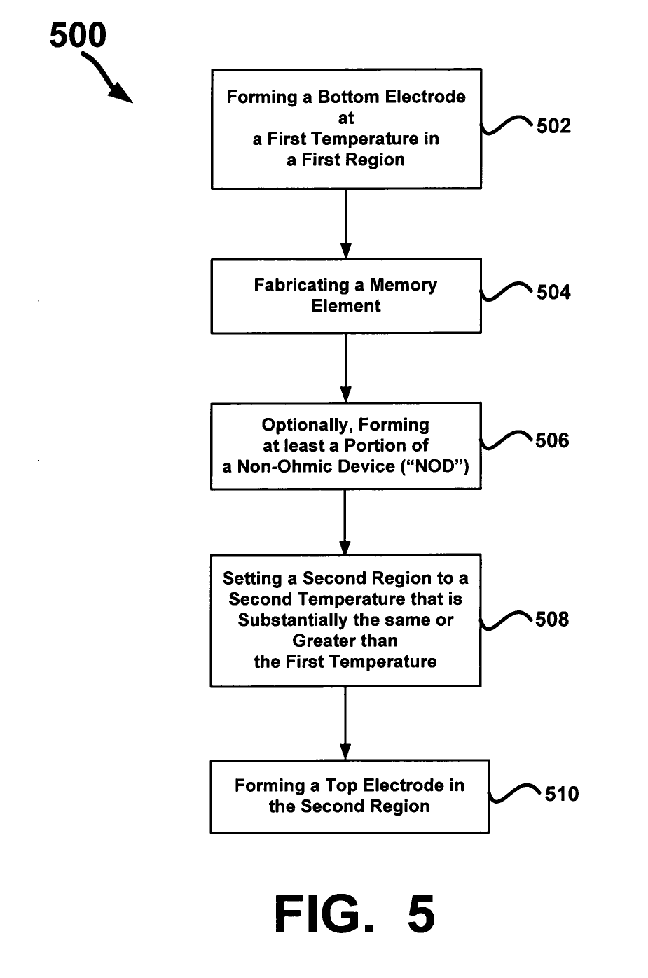

FIG. 5 depicts a flow 500 to form a non-volatile two-terminal memory cell that is scalable to provide different cross-sectional sizes while maintaining a uniform operational characteristic, according to various embodiments of the invention. At a stage 502, an electrode (e.g., a bottom electrode) can be formed at a first temperature in a first region. Next, a memory element can be fabricated at a stage 504 so as to couple the memory element to the bottom electrode (e.g., the memory element can be formed on top of the bottom electrode). Optionally, at a stage 506, at least a portion of a non-ohmic device (“NOD”) can be formed so as to electrically couple with the memory element. In some embodiments, the portion of the NOD can be a metal structure in a metal-insulator-metal (“MIM”) structure. Then, at a stage 508, a portion of flow describes setting a second region to a second temperature that is the same (or substantially the same) or greater than the first temperature. At a stage 510, an electrode (e.g., a top metal structure of a MIM structure) is deposited within the second region.

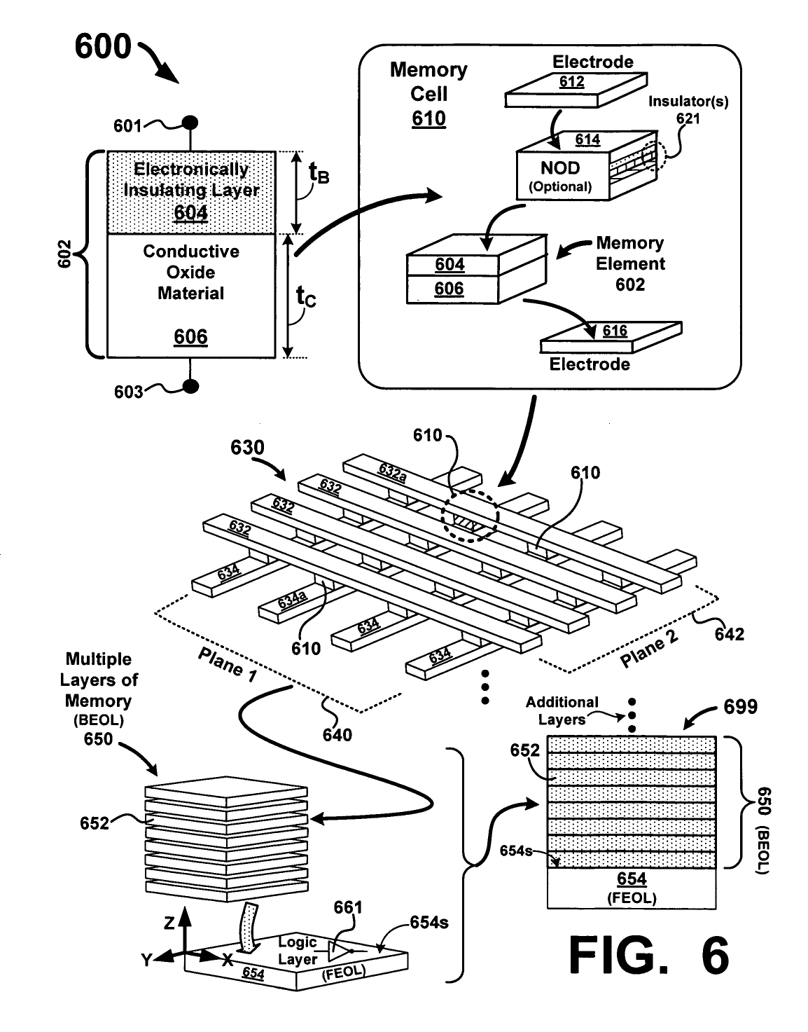

In specific embodiments, flow 500 can be modified to fabricate multiple layers of memory of two-terminal memory cells that are vertically positioned above and oriented parallel to a substrate (see FIG. 6). At least one of the layers of memory can be formed by setting a first region to a first temperature of approximately 300° C. or higher, and by setting a second region to a second temperature equivalent to the first temperature or higher, whereby setting the temperatures occurs during at least two intervals of time. A first platinum-based electrode and a second platinum-based electrode can be formed during the two intervals of time in which a line perpendicular to the substrate passes through at least a portion of the first platinum-based electrode and a portion of the second platinum-based electrode. In various embodiments, the first platinum-based electrode is a bottom electrode, whereas the second platinum-based electrode can be either a top electrode or an electrode between the top and the bottom electrodes. Next, flow 500 can be modified further to form a memory element between the second platinum-based electrode and the first platinum-based electrode. In some embodiments, the second platinum-based electrode and the first platinum-based electrode can be formed to include an insulator structure of a MIM structure. The memory element can be configured to provide a substantially uniform current density independent of the scaling of a cross-sectional area of the memory cell.

FIG. 6 depicts an example of a scalable array of memory cells each including a scalable memory element formed as part of a scalable memory cell, according to various embodiments of the invention. In this example, a memory cell 600 is formed to include a memory element 602, which, in turn, includes a structure 604 including an electronically insulating layer 604 disposed on a structure 606 including one or more layers of a conductive oxide material. The electronically insulating layer 604 has a thickness t_{B} that is approximately 50 Å or less. More preferably, the thickness t_{B} is 35 Å or less. The one or more layers of conductive oxide material 606 can have a combined thickness t_{C} that is approximately 350 Å or less. More preferably, the combined thickness t_{C} is approximately 270 Å or less. Memory cell 600 further includes terminals 601 and 603, which can be formed as electrode 612 and electrode 616, respectively, made from an electrically conductive material including, but not limited to, platinum (Pt) or similar electrically conductive materials or metals.

In at least some embodiments, memory element 602 can be formed as part of a memory cell 610. As shown, memory cell 610 can include an electrode structure 612 as terminal 601 formed upon a non-ohmic device (“NOD”) structure 614, which, in turn, can be formed upon memory element 602. Further, memory element 602 can be formed upon an electrode structure 616 as terminal 603. In some embodiments, electrode structures 612 and 616 can be formed using platinum at temperatures of approximately 300° C. or higher. In some embodiments, NOD structure 614 can include a MIM structure as any “metal-insulator-metal” structure denoted as layers 621. The layers 621 can be one or more layers of electronically insulating materials that are in contact with one another and sandwiched between and electrically in series with a pair of electrodes to form the MIM structure for NOD 614. In some embodiments, electrode structure 612 can be formed as a top metal layer of a MIM structure or can be formed on top of a MIM structure.

Memory cell 610 can be formed between conductive array lines, such as between array lines 632a and 634a. Thus, memory cell 610 can be one of a plurality of of other memory cells in an array, the array being a cross-point array 630 including groups of conductive array lines 632 and 634. To fabricate cross-point array 630, electrode structures 612 for the memory cells 610 between groups of conductive array lines 632 and 634 can be formed by, for example, depositing platinum-based material within or adjacent to one or more regions coextensive with “Plane 2” 642, whereby either the material or the regions, or both, are set to approximately 300° C. or higher. Similarly, electrode structures 616 in cross-point array 630 can be formed by, for example, depositing platinum-based material within or adjacent to one or more regions coextensive with “Plane 1” 640, whereby either the material or the regions, or both, are set to at least approximately 300° C. Further, cross-point array 630 can be formed as one layer 652 of memory in multiple layers of memory 650, which, in turn, is formed directly on top of a substrate 654 including a logic layer having active circuitry 661 and at least a portion of the active circuitry 661 is configured for data operations on the memory cells 610 in the multiple layers of BEOL memory 650. Since memory cells 610 are scalable in size, the scalable memory cells 610 facilitate the scaling of the size of cross-point array 630, such as in the X and Y planes. Thus, cross point array 630 can be described as a scalable array of memory cells. Here, the multiple layers of BEOL memory 650 are fabricated in contact with and above an upper surface 654s of the substrate 654. The upper surface 654s can represent the uppermost surface of an inter-level interconnect structure fabricated FEOL and operative to electrically couple signals from the active circuitry 661 with the conductive array lines 632 and 634. An integrated circuit 699 depicts the multiple layers of BEOL memory 650 fabricated directly above upper surface 654s of the substrate 654. The number of layers of BEOL memory will be application dependent and can include more or fewer layers than those depicted. The multiple layers of BEOL memory 650 and the substrate 654 are a contiguous unitary whole (e.g., a single die singulated from a silicon—Si wafer) that can be subsequently packaged in a suitable package for the integrated circuit 699.

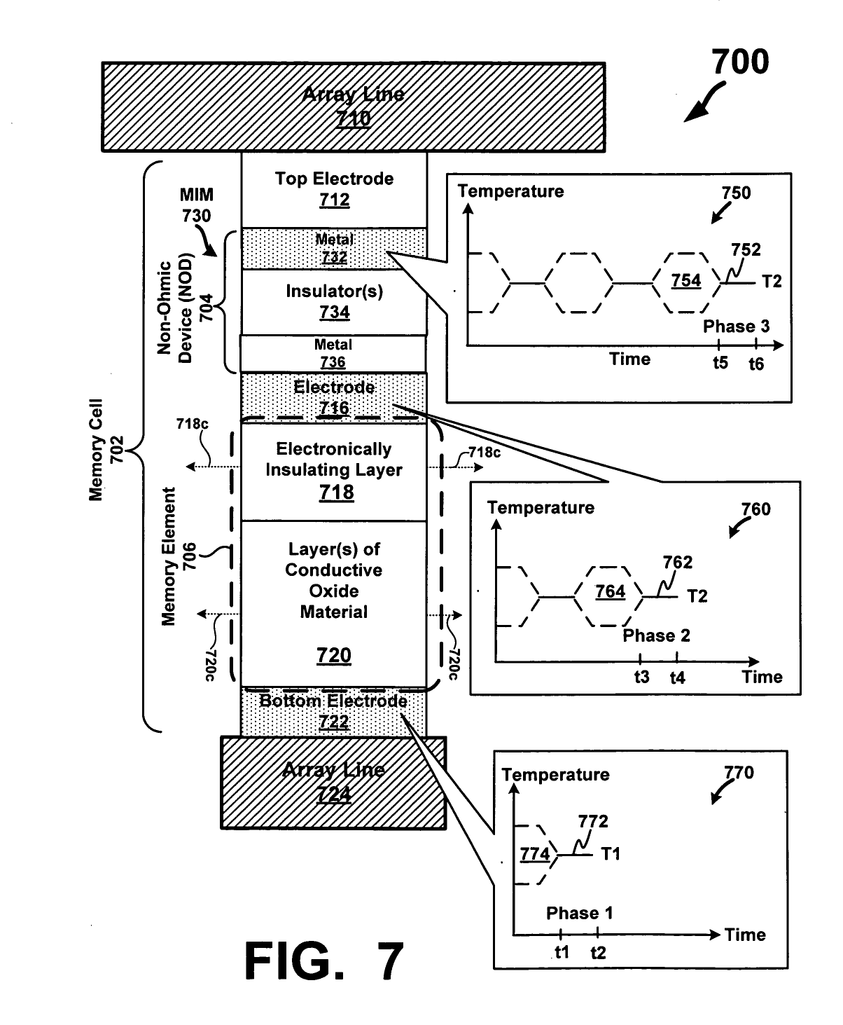

FIG. 7 depicts a side view of an exemplary memory cell formed in accordance with techniques described herein between conductive array lines, according to one or more embodiments. As shown in diagram 700, memory cell 702 includes a non-ohmic device (“NOD”) 704 and memory element 706 formed between conductive array lines 710 and 724. Memory cell 702 includes a bottom electrode 722, a structure including conductive oxide material 720 and an electronically insulating layer 718 (e.g., an electrolytic tunnel barrier layer) formed in contact with conductive oxide material 720. The layers 720 and 718 forming a memory element 706. In various embodiments, conductive oxide material 720 can include a material selected from one or more the following: a conductive perovskite materials including but are not limited to: manganites (e.g., PrCaMnOₓ—PCMO; LaCaMnOₓ—LCMO; LaSrMnOₓ—LSMO; PrMnOₓ—PMO; and LaSrCaMnOₓ—LSCMO); titanates (e.g., strontium titanate STO and a reduced STO); zirconates (SZO:Cr, CNO:Cr, TaO:Cr); SrRuOₓ—SRO; LaSrCrOₓ—LSCrO; LaNiOₓ—LNO; LaSrCrOₓ—LSCrO; and high Tc superconductors (e.g., YBCO); an electrically conductive binary oxide material including but not limited to a zinc oxide (ZnOₓ) (e.g., ZnO₂) and a doped titanium oxide (TiOₓ) (e.g., TiO₂). The titanium oxide (TiOₓ) can be doped with a material including but not limited to niobium (Nb). The doping of the titanium oxide (TiOₓ) can be accomplished by a process including but not limited to co-sputtering during deposition, and equivalent materials.

In turn, an electrode 716 is formed upon electrolytic tunnel barrier layer 718. In at least some embodiments, electronically insulating layer 718 can be an electrolytic tunnel barrier layer configured to provide for tunneling, which can include, but is not limited to, single step tunneling processes (e.g., direct tunneling, Fowler-Nordheim tunneling, and thermionic field emission tunneling), multi-step tunneling processes (e.g., trap-assisted tunneling), and the like. The electronically insulating layer 718 can be made from materials including but not limited to rare earth oxides, rare earth metal oxides, yttria stabilized zirconia (YSZ), yttrium oxide (Y₂O₃), zirconium oxide (ZrOₓ), also referred to as zirconia (e.g., ZrO₂), hafnium oxide (HfOₓ), gadolinium oxide (GdOx), lanthanum aluminum oxide (LaAlOₓ), erbium oxide (ErOₓ) (e.g., Er₂O₃), and the like. Next, a metal-insulator-metal (“MIM”) structure 730 that includes an insulator 734 is formed between metal structures 732 and 736, with MIM structure 730 being formed upon electrode 716. Examples of suitable materials for the one or more layers of insulating material 734 in NOD 704 include but are not limited to one or more of the following materials: SiO₂; Al₂O₃; SiNₓ; HfSiOₓ; ZrSiOₓ; Y₂O₃; Gd₂O₃; LaAlO₃; HfO₂; ZrO₂; Ta₂O₅; TiOₓ; yttria-stabilized zirconia (YSZ); Cr₂O₃; and BaZrO₃. Typical thickness for the one or more layers of insulating material 734 will be approximately 35 Å or less. As one example, given three insulating layers for 734, a first one of the layers can have a thickness of approximately 5 Å, a second one of the layers can have a thickness of approximately 15 Å, and a third one of the layers can have a thickness of approximately 10 Å. A top electrode 712 can be optionally formed thereupon. In some cases, metal structure 736 can be implemented as electrode 716.

Diagram 700 also illustrates temperature profiles associated with forming electrodes in accordance with some embodiments. Temperature profile 770 depicts the deposition of material to form bottom electrode 722 at a temperature T1 during phase (“1”) 772. Phase 772 extends between time t1 and time t2, and follows a period of time 774 during which previous semiconductor fabrication occurs (e.g., formation of array line 724). Temperature profile 760 depicts the deposition of material to form electrode 716 at a temperature T2 during phase (“2”) 762. Phase 762 extends between time t3 and time t4, and follows a period of time 764 during which memory element 706 is formed. Temperature profile 750 depicts the deposition of material to form metal structure 732 of a MIM at a temperature T2 during phase (“3”) 752. Phase 752 extends between time t5 and time t6, and follows a period of time 754 during which other portions of NOD 704 (e.g., insulator structure 734 and metal structure 736) are formed. In various embodiments, temperature T2 is greater than or equal to temperature T1. In some embodiments, the formation and associated temperature profiles are optional for one or more of top electrode 712 and electrode 716. Note that in either temperature profile 750 or profile 760 may be omitted from the fabrication process, according to some embodiments.

Although the layers 718 and 720 are depicted as being discrete layers, those layers can be continuous layers of thin film materials (e.g., layers 718 and 720 are not etched). The layers 718 and 720 can extend in a direction depicted by dashed arrows 718s and 720s (e.g., layers 720 and 718 can extend along the X and Y axes of FIGS. 2 and 6). To form memory elements 706 that are electrically in series with their respective electrodes (722, 712), portions of the layer(s) 720 that are substantially positioned under one or more of the layers (716, 704, 712) can be conductive oxide material that is electrically conductive and portions of the layer(s) 720 that are not positioned under the layers (716, 704, 712) can be made electrically non-conductive by ion implantation. Here, one or more of the layers (716, 704, 712) can serve as an implantation mask that prevents implant ions from bombarding the layer(s) 720 that are positioned under the layers (716, 704, 712); whereas, the layer(s) 720 that are not positioned under the layers (716, 704, 712) are bombarded by the implant ions and become electrically non-conductive. The ion implantation can also change a crystalline structure of the layer(s) 720 that are not positioned under the layers (716, 704, 712), by changing their structure from crystalline to amorphous, for example. The portions of the layer(s) 720 that are within the heavy dashed line for memory element 706 are not implanted and therefore retain their electrically conductive properties and their crystalline structure.

The various embodiments of the invention can be implemented in numerous ways, including as a system, a process, an apparatus, or a series of program instructions on a computer readable medium such as a computer readable storage medium or a computer network where the program instructions are sent over optical or electronic communication links. In general, the steps of disclosed processes can be performed in an arbitrary order, unless otherwise provided in the claims.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

what is claimed is:

1. A method for fabricating a non-volatile two-terminal memory device, comprising:
depositing back-end-of-the-line (BEOL), a first electrode at a first temperature in a first region, the first region is situated at a first distance from a substrate including active circuitry fabricated front-end-of-the-line (FEOL);
fabricating BEOL a memory element coupled with the first electrode;
forming BEOL at least a portion of a non-ohmic device (“NOD”) coupled with the memory element; and
depositing BEOL a second electrode at a second temperature in a second region situated at a second distance from the substrate, the second electrode being coupled via at least the memory element with the first electrode, thereby forming a memory cell,
wherein the second temperature is approximately greater than or equal to the first temperature.

2. The method as set forth in claim 1, wherein depositing the first electrode and depositing the second electrode respectively comprises
modifying a first thermal energy of the first region to obtain the first temperature during a first phase of forming the memory cell, and
modifying a second thermal energy of the second region to obtain the second temperature during a second phase of forming the memory cell.

3. The method as set forth in claim 2, and further comprising:
identifying a layer of memory cells in which to form the memory cell,
wherein the layer of memory cells includes the first region and the second region and is positioned above one or more other layers of memory cells of a third dimension memory array.

4. The method as set forth in claim 2, wherein the depositing the first electrode and the depositing the second electrode in the first phase and the second phase, respectively, further comprises
configuring the memory cell to facilitate scaling of a cross-sectional area of the memory cell in a range of cross-sectional area values in which a magnitude of current density is substantially uniform.

5. The method as set forth in claim 2, wherein the depositing the first electrode and the depositing the second electrode in the first phase and the second phase, respectively, further comprises
reducing an influence of one or more filamentary conduction paths on a current-voltage characteristics of the memory cell.

6. The method as set forth in claim 5, wherein reducing the influence of the one or more filamentary conduction paths comprises reducing one or more sizes of the one or more filamentary conduction paths.

7. The method as set forth in claim 1, wherein depositing the first electrode further comprises setting the first temperature to approximately 300° C. or higher.

8. The method as set forth in claim 1, wherein the depositing the first electrode and the depositing the second electrode comprises depositing a material including platinum or a platinum alloy to form the first electrode and the second electrode.

9. The method as set forth in claim 1, wherein the memory cell is configured to operate in accordance with substantially symmetric voltage and current relationships in a positive voltage range and a negative voltage range.

10. The method as set forth in claim 1, wherein the NOD comprises a metal-insulator-metal (MIM) structure including at least one layer of a dielectric material positioned between an intervening electrode and the second electrode, and wherein the second electrode is a metal portion of the MIM structure.

11. The method as set forth in claim 1, wherein fabricating the memory element further comprises forming an electronically insulating layer, and forming one or more layers of a conductive oxide material.

12. The method as set forth in claim 11, wherein forming the electronically insulating layer comprises fabricating a structure including a material selected from the group consisting of a rare earth oxide, a rare earth metal oxide, yttria stabilized zirconia, yttrium oxide, zirconium oxide, hafnium oxide, gadolinium oxide, lanthanum aluminum oxide, and erbium oxide.

13. The method as set forth in claim 11, wherein forming the one or more layers of the conductive oxide material comprises fabricating a structure including one or more materials selected from the group consisting of a magnanite, PCMO, LCMO, LSMO, PMO, LSCMO, a titanate, STO, a reduced STO, a zirconate, SRO, LSCrO, LNO, LSFeO, a high Tc superconductor, zinc oxide, and doped titanium oxide.

14. The method as set forth in claim 1 and further comprising:
forming electrically conductive paths between the active circuitry and the first and second electrodes.

15. The method as set forth in claim 1 and further comprising:
forming a plurality of first conductive array lines at a first plane coextensive with the first region, with at least one first conductive array line being coupled to the first electrode;
forming a plurality of second conductive array lines at a second plane coextensive with the second region, with at least one second conductive array line being coupled to the second electrode; and
electrically coupling the at least one first conductive array line and the at least one second conductive array line with the active circuitry.

16. A method for improving I-V curve symmetry and device scaling in a non-volatile two-terminal memory device, comprising:
forming back-end-of-the-line (BEOL), a plurality of two-terminal memory devices over a substrate, the substrate including active circuitry fabricated front-end-of-the-line (FEOL), each two-terminal memory device including
a bottom electrode deposited at a first temperature and operative as a first terminal of the two-terminal memory device,
at least one layer of a conductive oxide material, and
an electronically insulating layer deposited on top of the at least one layer of the conductive oxide material;
forming BEOL, a portion of a non-ohmic device (NOD) that is electrically in series with the two-terminal memory element in each two-terminal memory device by
depositing an electrode of the NOD on top of the electronically insulating layer, and
depositing at least one layer of a dielectric material on the electrode; and
depositing a top electrode on the at least one layer of dielectric material, the top electrode operative as a second terminal of the two-terminal memory element, wherein depositing the top electrode occurs at a second temperature that is approximately greater than or equal to the first temperature.

17. The method as set forth in claim 16, wherein the first temperature is approximately 300° C. or higher.

18. The method as set forth in claim 16, wherein a material for the top electrode and the bottom electrode comprises platinum or a platinum alloy.

19. The method as set forth in claim 16, wherein the at least one layer of the conductive oxide material comprises one or more materials selected from the group consisting of a magnanite, PCMO, LCMO, LSMO, PMO, LSCMO, a titanate, STO, a reduced STO, a zirconate, SRO, LSCrO, LNO, LSFeO, a high Tc superconductor, zinc oxide, and doped titanium oxide.

20. The method as set forth in claim 16, wherein the electronically insulating layer comprises material selected from the group consisting of a rare earth oxide, a rare earth metal oxide, yttria stabilized zirconia, yttrium oxide, zirconium oxide, hafnium oxide, gadolinium oxide, lanthanum aluminum oxide, and erbium oxide.

21. The method as set forth in claim 16, wherein the NOD comprises a metal-insulator-metal (MIM) structure including at least one layer of a dielectric material sandwiched between the electrode of the NOD and a top metal structure of the MIM.

22. The method as set forth in claim 16 and further comprising:
implanting ions in portions of the at least one layer of the conductive oxide material, wherein the at least one layer of the conductive oxide material is a continuous layer of material;
forming regions in the at least one layer of the conductive oxide material having an amorphous structure that is electrically insulating; and
using one or more layers of material positioned above the electronically insulating layer as an implantation mask to form masked portions of the at least one layer of the conductive oxide material that are masked by the one or more layers of material,
wherein the implantation mask is operative to prevent ion implantation of masked portions and operative to maintain the masked portions as a substantially crystalline and electrically conductive structure.

23. A method for fabricating a non-volatile two-terminal memory device, comprising:
fabricating back-end-of-the-line (BEOL), multiple layers of memory of two-terminal memory cells oriented parallel to a substrate including active circuitry fabricated front-end-of-the-line (FEOL),
forming at least one of the multiple layers of memory by
elevating a first region to a first temperature of 300° C. or higher and a second region to a second temperature equivalent to the first temperature or higher, during at least two intervals of time associated with the formation of the at least one of the multiple layers of memory,
forming a second platinum-based electrode and a first platinum-based electrode in which a line perpendicular to the substrate passes through at least a portion of the first platinum-based electrode and a portion of the second platinum-based electrode, and
forming a memory element between the second platinum-based electrode and the first platinum-based electrode, wherein the memory element is configured to provide a substantially uniform current density independent of a scaling of a cross-sectional area of the memory element.
